(19) United States
(12) Patent Application Publication
(10) Pub. No.: US 2012/0106759 A1
(43) Pub. Date: May 3, 2012

(54) SPEAKER SYSTEM AND METHOD FOR OPTIMIZING OUTPUT OF SPEAKER THEREOF

(75) Inventor: Yau-Wing Chung, Fremont, CA (US)

(73) Assignee: OPTOMA TECHNOLOGY, INC., Fremont, CA (US)

(21) Appl. No.: 13/110,020

(22) Filed: May 18, 2011

(30) Foreign Application Priority Data
Oct. 28, 2010 (TW) 99137005

(51) Int. Cl. H03G 3/00

(52) U.S. Cl. 381/107

(57) ABSTRACT

A speaker system and a method for optimizing an output of a speaker thereof are provided. The speaker system includes a speaker, an automatic gain control amplifier, a volume adjustment unit, a controller, and an indication unit. The function of the automatic gain control amplifier may be intelligently optimized by the controller, so that the controller may remind the user that the automatic gain control amplifier is operated in a reduced dynamic range through the indication unit in case that the volume adjustment unit receives an input sound frequency signal of a very high intensity. With the help of the indication unit, the user may easily find an optimal operation spot of the automatic gain control amplifier, and the speaker system may generate enough sound with a good dynamic range.

### CROSS-REFERENCE TO RELATED APPLICATION

This application claims the priority benefit of Taiwan application serial no. 99137005, filed Oct. 28, 2010. The entirety of the above-mentioned patent application is hereby incorporated by reference herein and made a part of this specification.

### BACKGROUND

1. Field of the Invention

The invention relates to an audio technology. Particularly, the invention relates to a low power speaker system and a method for optimizing an output of a speaker thereof.

2. Description of Related Art

Referring to FIG. 1, a speaker system 10 includes a volume adjustment unit 101, an amplifier 103, and a speaker 105. The amplifier 103 is used for amplifying an input sound frequency signal Si received and adjusted by the volume adjustment unit 101, so as to drive the speaker 105. Traditionally, if an intensity of the input sound frequency signal Si received by the volume adjustment unit 101 is inadequate, the speaker 105 may not play the received input sound frequency signal Si successfully.

Generally, a gain of the amplifier 103 can be increased to resolve the above problem. However, if a power output capability of the speaker system 10 is relatively low, the method of increasing the gain of the amplifier 103 may cause serious distortion of a sound output of the speaker 105. Even, in case that a power output of the speaker system 10 is excessively high, the speaker 105 can be damaged.

Therefore, in order to avoid the output distortion of the speaker 105 and protect the speaker 105 from being damaged, the amplifier 103 can be replaced by an automatic gain control (AGC) amplifier, so that when the intensity of the input sound frequency signal Si received by the volume adjustment unit 101 is higher than or lower than a preset threshold, the gain of the amplifier 103 can be automatically changed.

Unfortunately, the AGC amplifier itself has a usage limitation. Namely, if an automatic gain control (AGC) threshold of the AGC amplifier is set too high, the output distortion of the speaker 105 is still occurred when the volume adjustment unit 101 receives the input sound frequency signal Si with a high intensity.

In terms of a safety play, even if the AGC amplifier is applied in the speaker system 10, a maximum gain of the amplifier is still deliberately set to a relatively low optimum conservative value. Therefore, regarding the speaker system 10 that cannot generate enough sound, such deliberately set conservative gain value may lead to a fact that the sound generated by the speaker system 10 is weaker.

### SUMMARY OF THE INVENTION

Accordingly, the invention is directed to a speaker system, and the speaker system has a good sound quality.

The invention is directed to a method for optimizing an output of a speaker, and a speaker system may have a good sound quality by the method for optimizing the output of the speaker.

Additional aspects and advantages of the invention will be set forth in the description of the techniques disclosed in the invention.

To achieve one of or all aforementioned and other advantages, an embodiment of the invention provides a speaker system including a speaker, an automatic gain control amplifier, a volume adjustment unit, a controller, and an indication unit. The automatic gain control amplifier is coupled to the speaker, and is used for amplifying an input sound frequency signal to drive the speaker. The volume adjustment unit receives and adjusts the input sound frequency signal. The controller is coupled between the automatic gain control amplifier and the volume adjustment unit. When a sound volume of the speaker is changed in response to adjustment of the input sound frequency signal, the controller changes at least one of a gain and an automatic gain control threshold of the automatic gain control amplifier to generate a status instruction. The indication unit is coupled to the controller, and is used for indicating a dynamic range of the automatic gain control amplifier in response to the status instruction.

In an embodiment of the invention, after the controller changes the gain of the automatic gain control amplifier, the controller further determines whether the sound volume of the speaker is higher than a first predetermined value. When the controller determines that the sound volume of the speaker is higher than the first predetermined value, the controller reduces the automatic gain control threshold of the automatic gain control amplifier, otherwise, the controller maintains the automatic gain control threshold of the automatic gain control amplifier, and continually determines whether the input sound frequency signal is adjusted.

In an embodiment of the invention, after the controller reduces the automatic gain control threshold of the automatic gain control amplifier, the controller further determines whether the sound volume of the speaker is higher than a second predetermined value. When the controller determines that the sound volume of the speaker is higher than the second predetermined value, the controller generates the status instruction to enable an indication indicating that the automatic gain control amplifier is operated in a reduced dynamic range, and continually determines whether the input sound frequency signal is adjusted, otherwise, the controller disables the indication indicating that the automatic gain control amplifier is operated in the reduced dynamic range, and continually determines whether the input sound frequency signal is adjusted.

Another embodiment of the invention provides a method for optimizing an output of a speaker is described as follows. An input sound frequency signal is read and it is determined whether the input sound frequency signal is adjusted. When a sound volume of the speaker is changed in response to adjustment of the input sound frequency signal, at least one of a gain and an automatic gain control threshold of an automatic gain control amplifier used for driving the speaker is changed to generate a status instruction. A dynamic range of the automatic gain control amplifier is indicated in response to the status instruction, and a function of the automatic gain control amplifier is optimized.

In an embodiment of the invention, after the gain of the automatic gain control amplifier is changed, the method further includes determining whether the sound volume of the speaker is higher than a first predetermined value.

In an embodiment of the invention, when it is determined that the sound volume of the speaker is higher than the first predetermined value, the automatic gain control threshold of the automatic gain control amplifier is reduced, otherwise, the automatic gain control threshold of the automatic gain control amplifier is maintained, and it is continually determined whether the input sound frequency signal is adjusted.

In an embodiment of the invention, after reducing the automatic gain control threshold of the automatic gain control amplifier, the method further includes determining whether the sound volume of the speaker is higher than a second predetermined value.

In an embodiment of the invention, when it is determined that the sound volume of the speaker is higher than the second predetermined value, the status instruction is generated to enable an indication indicating that the automatic gain control amplifier is operated in a reduced dynamic range, and it is continually determined whether the input sound frequency signal is adjusted, otherwise, the indication indicating that the automatic gain control amplifier is operated in the reduced dynamic range is disabled, and it is continually determined whether the input sound frequency signal is adjusted.

In an embodiment of the invention, the second predetermined value may be greater than or equal to the first predetermined value.

According to the above descriptions, in the embodiments of the invention, the controller is used to intelligently optimize the function of the automatic gain control amplifier, so that in case that the volume adjustment unit receives an input sound frequency signal of a very high intensity, the controller may remind the user that the automatic gain control amplifier is operated in a reduced dynamic range through the indication unit. With the assistance of the indication unit, the user may easily find an optimal operation spot of the automatic gain control amplifier, so that the speaker system may have following advantages:

1. Wider dynamic range;

2. Lower output distortion;

3. Higher sound volume; and

4. The speaker is protected from being damaged in case of overloading.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a conventional speaker system.

FIG. 2 is a schematic diagram of a speaker system according to an embodiment of the invention.

FIG. 3 is a flowchart illustrating a method for optimizing an output of a speaker according to an embodiment of the invention.

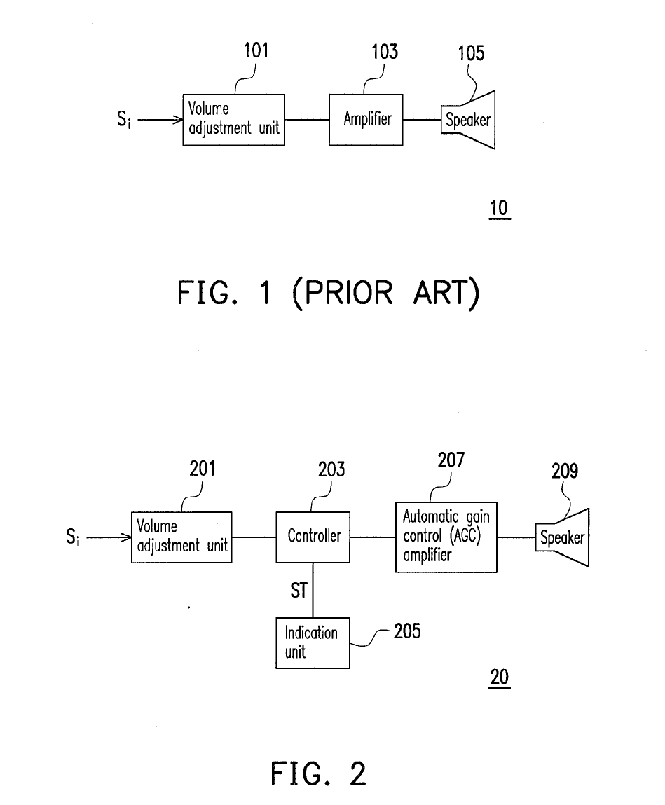

### DETAILED DESCRIPTION OF DISCLOSED EMBODIMENTS

It is to be understood that other embodiment may be utilized and structural changes may be made without departing from the scope of the invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings.

Referring to FIG. 2, a speaker system 20 of the present embodiment may be used in a music player device, for example, an MP3 player or similar player devices. In the present embodiment, the speaker system 20 includes a volume adjustment unit 201, a controller 203, an indication unit 205, an automatic gain control (AGC) amplifier 207, and a speaker 209. The controller 203 is coupled between the volume adjustment unit 201 and the automatic gain control amplifier 207 and is coupled to the indication unit 205. The automatic gain control amplifier 207 is coupled to the speaker 209.

The volume adjustment unit 201 receives and adjusts an input sound frequency signal Si. The input sound frequency signal Si is transmitted by an audio source, CD player, PC or laptop, or Smart phone, etc. The controller 203 changes at least one of a gain and an automatic gain control (AGC) threshold of the AGC amplifier 207 when a sound volume of the speaker 209 is changed in response to the adjustment of the input sound frequency signal Si performed by the volume adjustment unit 201 to generate a status instruction ST.

The AGC amplifier 207 of the embodiment amplifies the input sound frequency signal Si according to the gain and the AGC threshold set by the controller 203, so as to drive the speaker 209. In the embodiment, the indication unit 205 indicates a dynamic range of the AGC amplifier 207 in response to the status instruction ST generated by the controller 203. In the embodiment, the indication unit 205 may use a liquid crystal display module (LCM) to indicate the dynamic range of the AGC amplifier 207, though the invention is not limited thereto.

In the embodiment, the volume adjustment unit 201 adjusts the received input sound frequency signal Si in response to an operation of a user. In this way, the controller 203 accordingly changes the gain of the AGC amplifier 207, so that the AGC amplifier 207 amplifies the input sound frequency signal Si to drive the speaker 209. Meanwhile, the controller 203 determines whether the sound volume of the speaker 209 is higher than a first predetermined value (the first predetermined value may be set according to an actual design requirement), i.e. determines whether an output voltage of the AGC amplifier 207 is greater than the first predetermined value.

The controller 203 may obtain the sound volume of the speaker 209 according to the output voltage of the AGC amplifier 207. In detail, the controller 203 may obtain the output voltage of the AGC amplifier 207 according to an intensity of the received input sound frequency signal Si and the gain of the AGC amplifier 207. Alternatively, the controller 203 may use a volt meter to accurately measure the output voltage of the AGC amplifier 207, though the invention is not limited thereto.

When the controller 203 determines that the sound volume of the speaker 209 is higher than the first predetermined value (i.e. determines that the output voltage of the AGC amplifier 207 is greater than the first predetermined value), the controller 203 reduces the AGC threshold of the AGC amplifier 207, otherwise, the controller 203 maintains the AGC threshold of the AGC amplifier 207, and continually determines whether the input sound frequency signal Si is further adjusted.

When the controller 203 determines that the sound volume of the speaker 209 is lower than the first predetermined value (i.e. determines that the output voltage of the AGC amplifier 207 is less than the first predetermined value), it represents that the AGC amplifier 207 is now operated in a full dynamic range.

On the other hand, when the controller 203 determines that the sound volume of the speaker 209 is higher than the first predetermined value, it represents that an output distortion of the speaker 209 is probably occurred when the volume adjustment unit 201 receives the input sound frequency signal Si with a high intensity. Therefore, once the controller 203 determines that the sound volume of the speaker 209 is higher than the first predetermined value, the controller 203 reduces the AGC threshold of the AGC amplifier 207, so as to mitigate a possibility of distortion of the input sound frequency signal Si with the high intensity that is received by the volume adjustment unit 201.

In the embodiment of the invention, after the controller 203 reduces the AGC threshold of the AGC amplifier 207, the controller 203 further determines whether the sound volume of the speaker 209 is higher than a second predetermined value. (the second predetermined value may be greater than or equal to the first predetermined value according to an actual design requirement) (i.e. determines whether the output voltage of the AGC amplifier 207 is greater than the second predetermined value.) When the controller 203 determines that the sound volume of the speaker 209 is higher than the second predetermined value (i.e. determines that the output voltage of the AGC amplifier 207 is greater than the second predetermined value), the controller 203 generates the status instruction ST to enable an indication indicating that the AGC amplifier 207 is operated in a reduced dynamic range, and continually determines whether the input sound frequency signal Si is adjusted. Otherwise, the controller 203 disables the indication indicating that the AGC amplifier 207 is operated in the reduced dynamic range, and continually determines whether the input sound frequency signal Si is adjusted.

In other words, when the controller 203 reduces the AGC threshold of the AGC amplifier 207, and determines that the sound volume of the speaker 209 is higher than the second predetermined value, it represents that the intensity of the input sound frequency signal Si received by the volume adjustment unit 201 is excessively high, so that the controller 203 controls the indication unit 205 to indicate that the AGC amplifier 207 is operated in the reduced dynamic range (i.e. a compressed dynamic range), so as to remind the user to reduce the intensity of the input sound frequency signal Si received by the volume adjustment unit 201.

On the other hand, when the controller 203 reduces the AGC threshold of the AGC amplifier 207 and determines that the sound volume of the speaker 209 is lower than the second predetermined value, it represents that the intensity of the input sound frequency signal Si received by the volume adjustment unit 201 is within an acceptable range, i.e. the intensity of the input sound frequency signal Si received by the volume adjustment unit 201 is within a tolerance, so that the controller 203 controls the indication unit 205 to disable the indication indicating that the AGC amplifier 207 is operated in the reduced dynamic range.

According to the above descriptions, with the assistance of the indication unit 205, the user may easily find an optimal operation spot of the AGC amplifier 207, so that the speaker system 20 may generate enough sound within a good dynamic range.

Moreover, in other embodiments of the invention, the controller 203 may further send a volume instruction to the indication unit 205, so that the indication unit 205 may indicate an intensity of the sound volume of the speaker 209. Moreover, the controller 203 may also send other instructions to the indication unit 205, so that the indication unit 205 may indicate other related operation information of the speaker system 20.

In the embodiment of the invention, although the AGC amplifier 207 is taken as an example for description, in other embodiments of the invention, a digital amplifier and a digital signal processor/non-digital processor connected to the digital amplifier and having the AGC functionality may be used to replace the AGC amplifier 207. In this way, technical effects similar to that of the above embodiment may also be implemented.

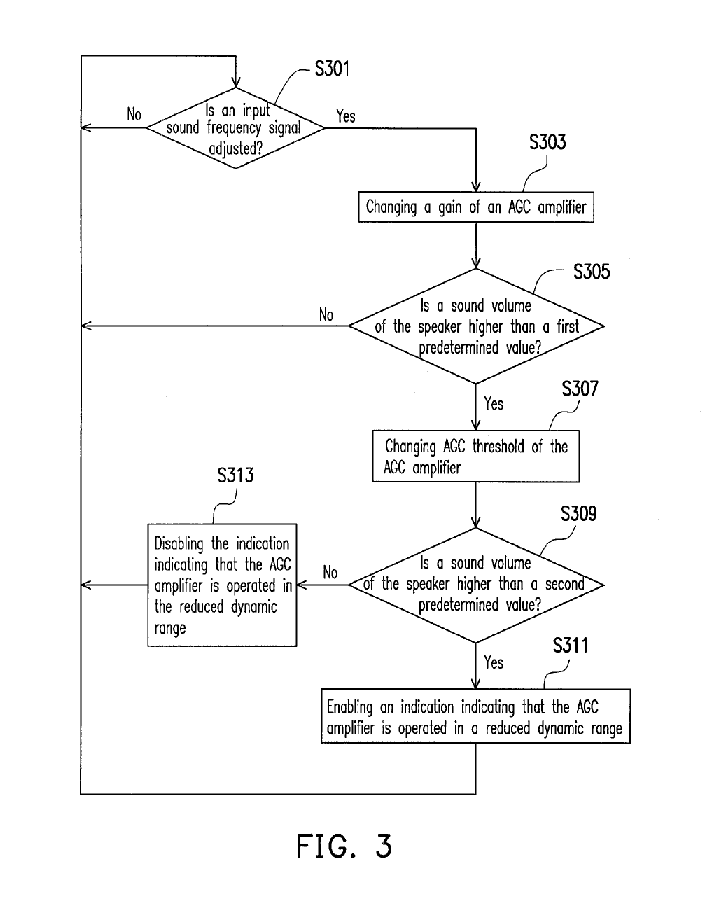

Based on the above descriptions, FIG. 3 may be interpreted as an operation method of the aforementioned controller 203 after configuration. Referring to FIG. 3, the method for optimizing the output of the speaker includes following steps.

An input sound frequency signal is read and it is determined whether the input sound frequency signal is adjusted (step S301).

When the input sound frequency signal is adjusted (which represents that a sound volume of a speaker is changed in response to the adjustment of the input sound frequency signal), a gain of an AGC amplifier used for driving the speaker is changed (step S303). Otherwise, the step S301 is repeated.

Once the gain of the AGC amplifier is changed, it is determined whether the sound volume of the speaker is higher than a first predetermined value (the first predetermined value may be set according to an actual design requirement, and the aforementioned embodiment mentioned above may be used to determine whether the sound volume of the speaker is higher than the first predetermined value) (step S305).

When it is determined that the sound volume of the speaker is higher than the first predetermined value, an AGC threshold of the AGC amplifier is changed (for example, reduced) (step S307). Otherwise, the AGC threshold of the AGC amplifier is maintained (which represents that the AGC amplifier is now operated in a full dynamic range), and the step S301 is repeated.

Once the AGC threshold of the AGC amplifier is changed (for example, reduced), it is determined whether the sound volume of the speaker is higher than a second predetermined value (the second predetermined value may be set to be greater than or equal to the first predetermined value according to an actual design requirement, and the aforementioned embodiment mentioned above may be used to determine whether the sound volume of the speaker is higher than the second predetermined value) (step S309).

When it is determined that the sound volume of the speaker is higher than the second predetermined value, a status instruction is generated to enable an indication indicating that the AGC amplifier is operated in a reduced dynamic range (i.e. a compressed dynamic range) (step S311), and the step S301 is repeated.

When it is determined that the sound volume of the speaker is lower than the second predetermined value, the indication indicating that the AGC amplifier is operated in the reduced dynamic range is disabled (step S313), and the step S301 is repeated.

According to the indication of the step S311, the function of the AGC amplifier used for driving the speaker may be optimized, so that the user may easily find an optimal operation spot of the AGC amplifier and the speaker system applying the AGC amplifier may generate enough sound within a good dynamic range.

In summary, in the embodiments of the invention, the controller is used to intelligently optimize the function of the automatic gain control amplifier, so that in case that the volume adjustment unit receives an input sound frequency signal of a very high intensity, the controller may remind the user that the automatic gain control amplifier is operated in a reduced dynamic range through the indication unit. With the assistance of the indication unit, the user may easily find an optimal operation spot of the automatic gain control amplifier, so that the speaker system may have following advantages:

1. Wider dynamic range;

2. Lower output distortion;

3. Higher sound volume; and

4. The speaker is protected from being damaged in case of overloading.

According to another aspect, presently, a plurality of video/audio contents produced by non-professionals is placed on websites for others to watch. However, since most of the produced input sound signals are not encoded or recorded according to standard video/audio specifications, some of the played sounds are excessively large and some of the played sounds are excessively weak. Therefore, by using the speaker system and the method of the invention, the sounds produced without obeying the specifications may be played in accordance with the standard as far as possible.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A speaker system, comprising:
a speaker;
an automatic gain control amplifier, coupled to the speaker, for amplifying an input sound frequency signal to drive the speaker;
a volume adjustment unit, for receiving and adjusting the input sound frequency signal;
a controller, coupled between the automatic gain control amplifier and the volume adjustment unit, wherein when a sound volume of the speaker is changed in response to adjustment of the input sound frequency signal, the controller changes at least one of a gain of the automatic gain control amplifier and an automatic gain control threshold of the automatic gain control amplifier to generate a status instruction; and
an indication unit, coupled to the controller, for indicating a dynamic range of the automatic gain control amplifier in response to the status instruction.

2. The speaker system as claimed in claim 1, wherein after the controller changes the gain, the controller further determines whether the sound volume of the speaker is higher than a first predetermined value, wherein when the controller determines that the sound volume of the speaker is higher than the first predetermined value, the controller reduces the automatic gain control threshold of the automatic gain control amplifier, otherwise, the controller maintains the automatic gain control threshold of the automatic gain control amplifier, and continually determines whether the input sound frequency signal is adjusted.

3. The speaker system as claimed in claim 2, wherein after the controller reduces the automatic gain control threshold of the automatic gain control amplifier, the controller further determines whether the sound volume of the speaker is higher than a second predetermined value, wherein when the controller determines that the sound volume of the speaker is higher than the second predetermined value, the controller generates the status instruction to enable an indication indicating that the automatic gain control amplifier is operated in a reduced dynamic range, and continually determines whether the input sound frequency signal is adjusted, otherwise, the controller disables the indication indicating that the automatic gain control amplifier is operated in the reduced dynamic range, and continually determines whether the input sound frequency signal is adjusted.

4. The speaker system as claimed in claim 3, wherein the second predetermined value is greater than or equal to the first predetermined value.

5. A method for optimizing an output of a speaker, comprising:
reading and determining whether an input sound frequency signal is adjusted;
when a sound volume of the speaker is changed in response to adjustment of the input sound frequency signal, at least one of a gain and an automatic gain control threshold of an automatic gain control amplifier used for driving the speaker is changed to generate a status instruction; and
indicating a dynamic range of the automatic gain control amplifier in response to the status instruction to optimize the automatic gain control amplifier.

6. The method for optimizing the output of the speaker as claimed in claim 5, wherein after changing the gain, the method further comprises:
determining whether the sound volume of the speaker is higher than a first predetermined value.

7. The method for optimizing the output of the speaker as claimed in claim 6, wherein when it is determined that the sound volume of the speaker is higher than the first predetermined value, the automatic gain control threshold is reduced, otherwise, the automatic gain control threshold is maintained, and it is continually determined whether the input sound frequency signal is adjusted.

8. The method for optimizing the output of the speaker as claimed in claim 7, wherein after reducing the automatic gain control threshold, the method further comprises:
determining whether the sound volume of the speaker is higher than a second predetermined value.

9. The method for optimizing the output of the speaker as claimed in claim 8, wherein
when it is determined that the sound volume of the speaker is higher than the second predetermined value, the status instruction is generated to enable an indication indicating that the automatic gain control amplifier is operated in a reduced dynamic range, and it is continually determined whether the input sound frequency signal is adjusted, otherwise, the indication indicating that the automatic gain control amplifier is operated in the reduced dynamic range is disabled, and it is continually determined whether the input sound frequency signal is adjusted.

10. The method for optimizing the output of the speaker as claimed in claim 8, wherein the second predetermined value is greater than or equal to the first predetermined value.
